(19) United States
(12) Patent Application Publication
(10) Pub. No.: US 2014/0203829 A1
(43) Pub. Date: Jul. 24, 2014

(54) TEST JIG AND SEMICONDUCTOR DEVICE TEST METHOD

(71) Applicant: FUJITSU LIMITED, Kawasaki-shi (JP)

(72) Inventor: Hiroshi Yamada, SAPPORO (JP)

(73) Assignee: FUJITSU LIMITED, Kawasaki-shi (JP)

(21) Appl. No.: 14/220,627

(22) Filed: Mar. 20, 2014

Related U.S. Application Data
(63) Continuation of application No. PCT/JP2011/072823, filed on Oct. 4, 2011.

(51) Int. Cl. G01R 1/04; G01R 31/26

(52) U.S. Cl. CPC G01R 1/0408; G01R 31/26
USPC 324/750.08; 324/750.01

(57) ABSTRACT

The test jig includes: a package mounting plate on which a semiconductor device is placed; a plurality of penetrating holes provided in the package mounting plate; a socket portion in which a plurality of probe pins are disposed, the probe pins designed to come in contact with electrodes of the semiconductor device through the penetrating holes; and a gas injecting unit configured to inject gas to the package mounting plate through the socket portion. The test of the semiconductor device is performed with the gas injected from the gas injecting unit to the package mounting plate.

### CROSS-REFERENCE TO RELATED APPLICATION

This application is a continuation of International Patent Application No. PCT/JP2011/072823 filed Oct. 4, 2011 and designated the U.S., the entire contents of which are incorporated herein by reference.

### FIELD

The embodiments discussed herein are related to a test jig and a semiconductor device test method.

### BACKGROUND

Semiconductor devices (LSI: Large Scale Integrated circuits) as CPUs (Central Processing Units) and the like used in high-performance servers generate a large amount of heat in operation. In order to secure long-term reliability, it is important to subject such a semiconductor device to an accelerated test and check presence and absence of defects before the semiconductor device is mounted on a motherboard.

In the accelerated test, large load is applied to the semiconductor device by, for example, applying a voltage higher than a specified voltage or supplying a signal with a frequency higher than a specified frequency. In such an accelerated test, heat corresponding to the load is generated in the semiconductor device and the temperature of the semiconductor device may exceed a destruction temperature. Accordingly, in the accelerated test, the semiconductor device is cooled to the destruction temperature or below by attaching a heat sink to the semiconductor device and sending cool air to the heat sink with an air blowing fan. Meanwhile, for some semiconductor device with a small amount of heat generation, the accelerated test is performed with the semiconductor device placed in a constant temperature oven and heated to a predetermined temperature.

### Patent Literature 1: Japanese Laid-open Patent Publication No. 2003-86748

### Patent Literature 2: Japanese Laid-open Patent Publication No. 2008-98556

### Patent Literature 3: Japanese Laid-open Patent Publication No. 01-175298

### Patent Literature 4: Japanese Laid-open Patent Publication No. 2007-5685

### SUMMARY

One aspect of the disclosed technique provides a test jig including: a package mounting plate on which a semiconductor device is placed; a plurality of penetrating holes provided in the package mounting plate; a socket portion in which a plurality of probe pins are disposed, the probe pins designed to come in contact with electrodes of the semiconductor device through the plurality of penetrating holes; and a gas injecting unit configured to inject gas to the package mounting plate through the socket portion.

Another aspect of the disclosed technique provides a semiconductor device test method of testing a semiconductor device by: placing the semiconductor device on a test jig in which a probe pin is installed; and supplying a signal from a controller to the semiconductor device via the probe pin, wherein the test jig includes: a package mounting plate on which the semiconductor device is placed; a penetrating hole provided in the package mounting plate and allowing insertion of a front end portion of the probe pin; a socket portion in which the probe pin is disposed; and a gas injecting unit configured to inject gas, and the method comprises testing the semiconductor device while injecting the gas from the gas injecting unit to the package mounting plate through the socket portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic cross-sectional view of a test jig according to an embodiment;

FIG. 2 is an assembly view of the test jig;

FIG. 3 is a top view of a package mounting plate;

FIG. 4 is a schematic cross-sectional view of a probe pin;

FIG. 5 is a schematic view explaining a semiconductor device test method by using the test jig according to the embodiment;

FIG. 6 is a view explaining the thermal resistance in the test jig of the embodiment;

FIGS. 7A and 7B are schematic views illustrating Modified Example 1;

FIG. 8A is a schematic top view of a test jig of Modified Example 2 and FIG. 8B is a schematic side view of the test jig;

FIGS. 9A and 9B are schematic views illustrating a test jig of Modified Example 3;

FIG. 10 is a schematic view illustrating a test jig of Modified Example 4;

FIG. 11 is a graph explaining an example of PID control;

FIG. 12 is a schematic view of a test jig of a comparative example;

FIG. 13 is a view illustrating a temperature change of a CPU in an example; and

FIG. 14 is a view illustrating a portion surrounded by a broken line in FIG. 13 in an enlarged manner.

### DESCRIPTION OF EMBODIMENTS

In a recent semiconductor device, an operating current greatly changes in an instant due to use of higher clock frequency. When the operating current greatly changes in an instant, the temperature of the semiconductor device (junction temperature) also rapidly changes.

As described above, the semiconductor device is conventionally cooled by attaching a heat sink to the semiconductor device and sending a cool air to the heat sink with an air blowing fan. However, due to a high thermal resistance, this method has difficulty in coping with a rapid temperature change of the semiconductor device. Hence, the temperature of the semiconductor device reaches a destruction temperature in some cases.

In the following embodiment, description is given of a test jig which may cope with a rapid temperature change of a semiconductor device and which may perform a test while preventing destruction of the semiconductor device, and a semiconductor device test method by using the test jig.

### Embodiment

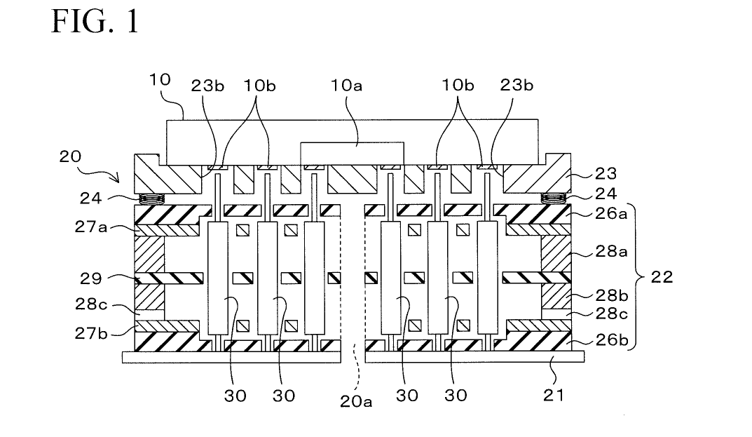

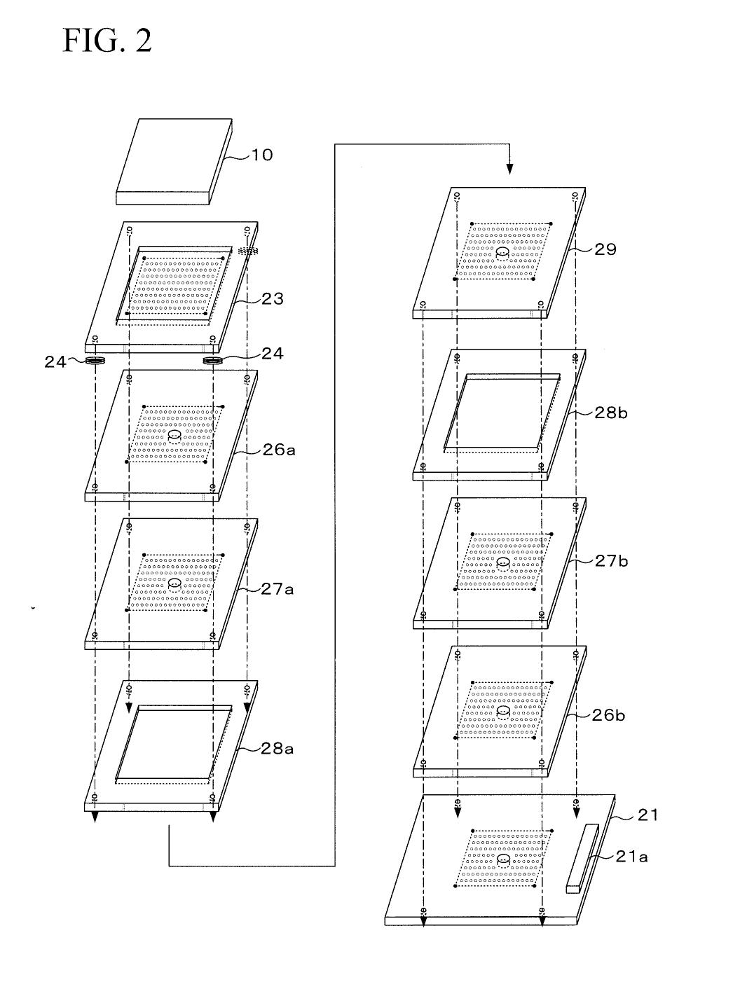

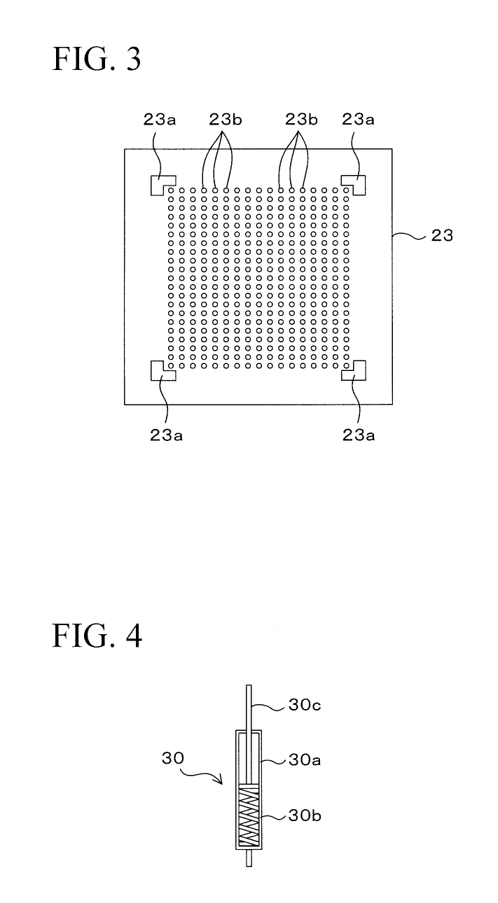

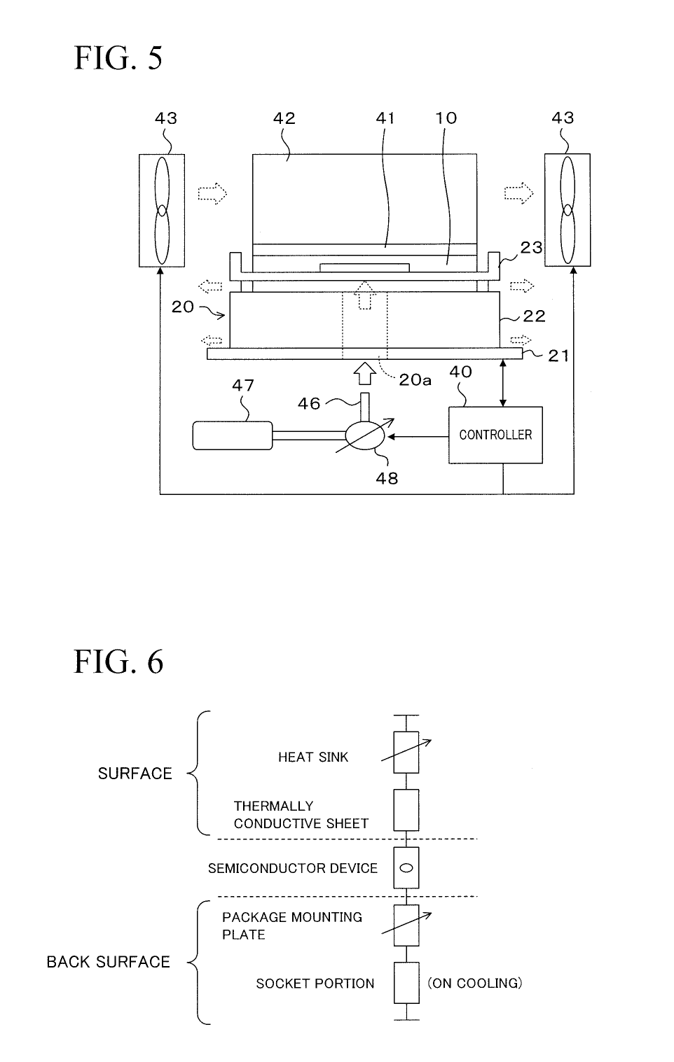

FIG. 1 is a schematic cross-sectional view of a test jig according to the embodiment and FIG. 2 is an assembly view of the test jig. Moreover, FIG. 3 is a top view of a package mounting plate and FIG. 4 is a schematic cross-sectional view of a probe pin. Furthermore, FIG. 5 is a schematic view explaining a semiconductor device test method by using the test jig according to the embodiment.

The test jig 20 according to the embodiment includes a printed board 21, a socket portion 22, and a package mounting plate 23. The printed board 21 is fixed to a lower portion of the socket portion 22. Moreover, the package mounting plate 23 is supported on the socket portion 22 by a plurality of coil springs 24 to be movable in an up-down direction.

A semiconductor device (IC package) 10 which is a test target is mounted on the package mounting plate 23. In the embodiment, description is given of a case where the semiconductor device 10 is a LGA (Land Grid Array) semiconductor device. However, the disclosed technique may be also applied to a semiconductor of a BGA (Ball Grid Array) type or other types. Note that reference numeral 10a in FIG. 1 denotes a semiconductor chip encapsulated in the semiconductor device 10 and reference numeral 10b denotes external connection electrodes of the semiconductor device 10.

As illustrated in FIG. 3, a plurality of protrusions (guides) 23a defining a mounting position of the semiconductor device 10 are provided on a top surface of the package mounting plate 23 and the semiconductor device 10 is placed on the inner side of the protrusions 23a in an accelerated test. Moreover, holes 23b in which front end portions 30c of probe pins 30 to be described later are inserted are provided in the package mounting plate 23 at positions corresponding to the electrodes 10b of the semiconductor device 10.

The package mounting plate 23 is preferably made of a material with excellent thermal conductivity. In the embodiment, the package mounting plate 23 is assumed to be made of metal such as copper or aluminum.

The socket portion 22 has a structure in which a probe pin holding plate 26b, a heat dissipating plate 27b, a heat storing plate 28b, an alignment plate 29, a heat storing plate 28a, a heat dissipating plate 27a, and a probe pin holding plate 26a are stacked one on top of another in this order from a lower side. Moreover, an air flow passage 20a (illustrated by broken lines in FIG. 1) penetrating the socket portion 22 and the printed board 21 from a bottom surface side to a top surface side is provided in center portions of the socket portion 22 and the printed board 21.

Many probe pins 30 electrically connecting electrodes (not illustrated) of the printed board 21 and the electrodes 10b of the semiconductor device 10 to one another are disposed in the socket portion 22. For example, as illustrated in FIG. 4, these probe pins 30 each include a cylindrical supporting portion 30a, a coil spring 30b disposed in the supporting portion 30a, and the front end portion 30c biased upward by the coil spring 30b.

The probe pins 30 are supported by the probe pin holding plate 26a disposed in an upper portion of the socket portion 22, the probe pin holding plate 26b disposed in a lower portion of the socket portion 22, and the alignment plate 29 disposed in a center portion of the socket portion 22, with axial directions of the probe pins 30 being vertical.

Specifically, penetrating holes having substantially the same diameter as the diameter of the probe pins 30 are provided at a predetermined pitch in each of the probe pin holding plates 26a, 26b and the alignment plate 29 and the probe pins 30 are vertically disposed to be inserted through the penetrating holes. The probe pin holding plates 26a, 26b and the alignment plate 29 are made of an insulating resin to avoid short circuit among the probe pins 30.

The heat dissipating plates 27a, 27b and the heat storing plates 28a, 28b are made of metal such as copper or aluminum. Penetrating holes having a diameter larger than the diameter of the probe pins 30 are provided in the heat dissipating plates 27a, 27b at positions corresponding to the probe pins 30 and the heat dissipating plates 27a, 27b are thus designed not to come in contact with the probe pins 30.

Moreover, the heat storing plates 28a, 28b are each formed in a frame shape in which a center portion where the probe pins 30 are arranged is hollow. Accordingly, the heat storing plates 28a, 28b also do not come in contact with the probe pins 30. Holes 28c through which a space inside the socket portion 22 and a space outside the socket portion 22 communicate with each other are provided at predetermined positions of the heat storing plate 28b.

Lower ends of the probe pins 30 come in contact with the electrodes of the printed board 21. A connector 21a (see FIG. 2) is provided in an edge portion of the printed board 21 and the electrodes of the printed board 21 and a controller 40 are electrically connected to each other via the connector 21a (see FIG. 5). The controller 40 is a main body portion of a test apparatus including a computer.

In the embodiment, since the package mounting plate 23 is made of metal, the probe pins 30 may be electrically connected to each other via the package mounting plate 23.

However, in the embodiment, the probe pins 30 are vertically supported by the probe pin holding plates 26a, 26b and the alignment plate 29 and the diameter of the holes 23b of the package mounting plate 23 is set to be substantially larger than the diameter of the front end portions 30c of the probe pins 30. Accordingly, in the embodiment, it may be possible to avoid contact between the probe pins 30 and the package mounting plate 23 and prevent the probe pins 30 from being electrically connected to each other via the package mounting plate 23. In order to more effectively prevent the electrical connection among the probe pins 30 via the package mounting plate 23, wall surfaces of the holes 23b of the package mounting plate 23 may be covered with insulating material.

An example of the semiconductor device test method by using the test apparatus described above is described below with reference to FIG. 5. Here, a temperature sensor is included in the semiconductor device 10 and an output of the temperature sensor is inputted to the controller 40 via the electrodes 10b, the probe pins 30, the connector 21a of the printed board 21, and the like. Alternatively, the temperature sensor may be configured such that the temperature sensor is attached to the surface of the semiconductor device 10 or the surface of the package mounting plate 23 and the output of the temperature sensor is inputted to the controller 40.

First, as illustrated in FIG. 5, a heat sink 42 is attached onto the semiconductor device 10 with a thermally conductive sheet (thermal sheet) 41 interposed therebetween. Then, the semiconductor device 10 is placed on the package mounting plate 23 of the test jig 20.

When the semiconductor device 10 to which the heat sink 42 is attached is placed on the package mounting plate 23, the coil springs 24 are compressed by the weight of the semiconductor device 10 and the package mounting plate 23 moves downward, thereby causing the electrodes 10b of the semiconductor device 10 and the front end portions 30c of the probe pins 30 to come in contact with one another. In this case, since the coil springs 30b are provided in the probe pins 30, the electrodes 10b of the semiconductor device 10 and the front end portions 30c of the probe pins 30 come in contact with one another at pressure determined by the elastic force of the coil springs 30. This avoids contact failure between the electrodes 10b and the probe pins 30.

Next, air blowing fans 43 whose drives are controlled by the controller 40 are disposed on both sides (or on one side) of the heat sink 42. Moreover, an air nozzle 46 is disposed below the test jig 20 at a position aligned with the air flow passage 20a. The air nozzle 46 is connected to an air supplying device 47 via an air valve (flow rate adjusting valve) 48 controlled by the controller 40.

Then, a voltage higher than a specified voltage is applied from the controller 40 to the semiconductor device 10 via the probe pins 30 or a signal with a frequency higher than a specified frequency is supplied from the controller 40 to the semiconductor device 10 via the probe pins 30 to cause the semiconductor device 10 to operate in a high-load condition. The controller 40 determines whether the semiconductor device 10 is defective or not on the basis of a signal outputted from the semiconductor device 10.

Incidentally, heat is generated along with the operation of the semiconductor device 10 and the temperature of the semiconductor device 10 rises. In order to avoid destruction of the semiconductor device 10 due to heat, it is important to keep the temperature of the semiconductor device 10 equal to or below the destruction temperature.

Part of the heat generated by the semiconductor device 10 moves to the heat sink 42 via the thermally conductive sheet 41. When the temperature of the semiconductor device 10 detected by the temperature sensor exceeds a set temperature set in advance, the controller 40 causes the air blowing fans 43 to operate. This cools the heat sink 42 and the temperature of the semiconductor device 10 drops. Note that the set temperature is set to a temperature lower than the destruction temperature.

Moreover, in the embodiment, since the package mounting plate 23 is made of metal with excellent thermal conductivity such as copper or aluminum, part of the heat generated by the semiconductor device 10 quickly moves from a bottom surface of the semiconductor device 10 to the package mounting plate 23.

When the temperature of the semiconductor device 10 detected by the temperature sensor exceeds a set temperature set in advance, the controller 40 opens the air valve 48 and causes compressed air supplied from the air supplying device 47 to blow on the bottom surface of the package mounting plate 23 through the air flow passage 20a. As illustrated in FIG. 5, the air blowing on the bottom surface of the package mounting plate 23 moves in horizontal directions along the package mounting plate 23. This air cools the package mounting plate 23 and the temperature of the semiconductor device 10 thereby drops.

The set temperature at which the air blowing fans 43 are made to operate may be the same as or different from the set temperature at which the air valve 48 is opened. Moreover, air is an example of a gas and gases other than air such as nitrogen gas or carbon dioxide gas may be used as the gas.

As described above, in the embodiment, since the semiconductor device 10 is cooled not only from the upper side but also from the lower side (electrode surface side), the cooling performance is great. Accordingly, destruction due to heat may be avoided even in a semiconductor device with a large amount of heat generation.

Moreover, in the embodiment, since the package mounting plate 23 is made of metal with excellent heat conductivity, the thermal resistance between the semiconductor device 10 and the package mounting plate 23 is small and the thermal capacity is large. Accordingly, even when the temperature of the semiconductor device 10 instantaneously rises, the heat quickly moves from the semiconductor device 10 to the package mounting plate 23. This may effectively avoid the case where the temperature of the semiconductor device 10 reaches the destruction temperature in the accelerated test.

FIG. 6 is a view explaining the thermal resistance in the test jig of the embodiment. In FIG. 6, a variable resistance on the upper side represents the thermal resistance of the heat sink 42 and indicates that the thermal resistance changes depending on the rotation of the air blowing fans 43. Moreover, a variable resistance on the lower side represents the thermal resistance of the package mounting plate 23 and indicates that the thermal resistance changes depending on the air blowing from the air nozzle 46.

The embodiment also has the following effects.

Specifically, the heat is also transmitted from the electrodes 10a of the semiconductor device 10 to the probe pins 30 and the temperatures of the probe pins 30 thereby rise. Moreover, heat is generated by currents flowing through the probe pins 30 in portions where the electrical resistance is high, for example, a contact portion between the coil spring 30b and the front end portion 30c in each of the probe pins 30, and the temperatures of the probe pins 30 thereby further rise. This may cause the temperature of the test jig 20 to become high and make sufficient cooling of the semiconductor device 10 difficult.

However, in the embodiment, since the metal heat dissipating plates 27a, 27b are disposed close to the probe pins 30, the heat moves from the probe pins 30 to the heat dissipating plates 27a, 27b relatively easily. Moreover, the heat having moved to the heat dissipating plates 27a, 27b further moves to the metal heat storing plates 28a, 28b which have large thermal capacities.

Then, as illustrated in FIG. 5, part of the air injected from the air nozzle 46 and entering the socket portion 22 moves in the horizontal directions in the socket portion 22 and is discharged from the holes 28c to the outside. This air cools the heat dissipating plates 27a, 27b and the heat storing plates 28a, 28b and suppresses rise of the temperatures of the probe pins 30 and the test jig 20.

Modified examples of the embodiment are described below.

### Modified Example 1

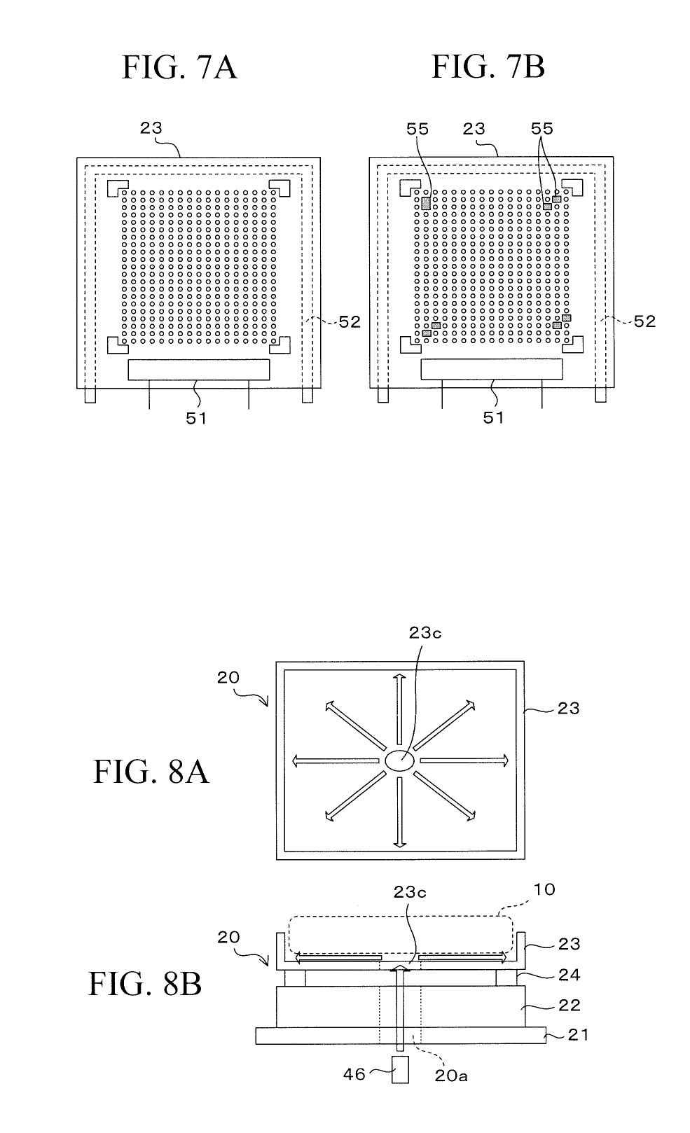

FIGS. 7A and 7B are views illustrating Modified Example 1. As illustrated in FIGS. 7A and 7B, for example, a heater or a Peltier element may be attached to the package mounting plate 23 as a temperature adjustor 51. The semiconductor device may be thereby heated and set to a predetermined temperature by the temperature adjustor 51 in a case where the amount of heat generation of the semiconductor device is small and the temperature of the semiconductor device does not rise to the predetermined temperature.

Moreover, a heating medium flow passage 52 through which a heating medium (for example, cooling water or warm water) flows may be provided in the package mounting plate 23. Furthermore, cooling fins (not illustrated) may be attached to the package mounting plate 23. The heating medium flow passage 52, the cooling fins, and the like may enable more precise control of the temperature of the semiconductor device 10.

Furthermore, as illustrated in FIG. 7B, connection terminals 55 thermally connected to grounding terminals (GND terminals) of the semiconductor device 10 may be provided at portions corresponding to the ground terminals. This further improves the heat transfer efficiency from the semiconductor device 10 to the package mounting plate 23.

### Modified Example 2

FIG. 8A is a schematic top view of a test jig of Modified Example 2 and FIG. 8B is a schematic side view of the test jig. Note that white outline arrows in FIGS. 8A and 8B indicate flow directions of air.

As illustrated in FIGS. 8A and 8B, a hole 23c penetrating the package mounting plate 23 from the upper side to the lower side may be provided in the center portion of the package mounting plate 23. In this case, part of the air injected from the air nozzle 46 passes through the hole 23c, reaches the bottom surface of the semiconductor device 10, and moves in horizontal directions along the bottom surface of the semiconductor device 10.

In the embodiment (see FIG. 5) described above, the air injected from the air nozzle 46 cools the package mounting plate 23. Meanwhile, in Modified Example 2, the air injected from the air nozzle 46 directly cools the semiconductor device 10. Accordingly, the cooling efficiency is further improved. Moreover, in Modified Example 2, since the air directly blows on the semiconductor device 10, the test jig may cope with instantaneous temperature rise of the semiconductor device 10 more quickly and avoid destruction of the semiconductor device 10 due to heat more effectively.

### Modified Example 3

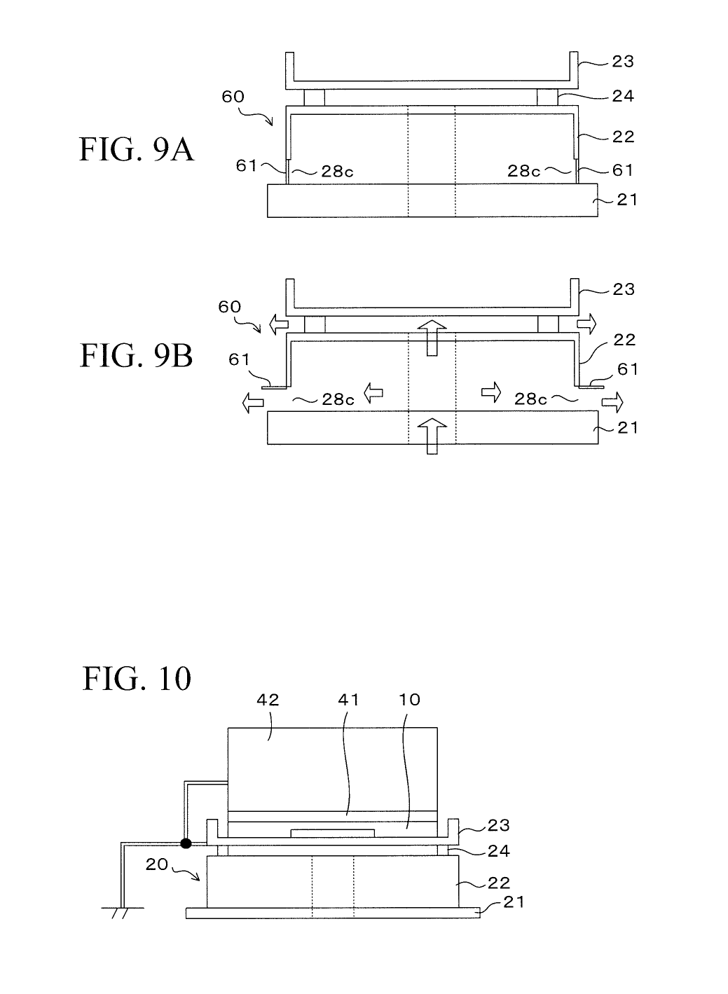

FIGS. 9A and 9B are schematic views illustrating a test jig of Modified Example 3. In the test jig 60 of Modified Example 3, dampers 61 which are opened and closed by wind pressure are provided in the holes 28c provided in the side portions of the socket portion 22. FIG. 9A illustrates a state where the dampers 61 are closed and FIG. 9B illustrates a state where the dampers 61 are opened.

In the case where the amount of heat generation of the semiconductor device 10 is small, the semiconductor device 10 prefers to be heated to a predetermined temperature in the accelerated test in some cases. In the test jig 60 of Modified Example 3, the holes 28c are closed by the dampers 61 when no air is blowing out from the air nozzle 46 (not illustrated in FIGS. 9A and 9B). Then, heat generated in the probe pins 30 (particularly in the connection portions between the coil springs 30b and the front end portions 30c: see FIG. 4) by signals flowing in the probe pins 30 is transmitted to the semiconductor device 10 via the probe pins 30 and the package mounting plate 23. This heat may promote the temperature rise of the semiconductor device 10 and energy for heating the semiconductor device 10 may be thereby reduced.

### Modified Example 4

FIG. 10 is a schematic view illustrating a test jig of Modified Example 4.

When the heat sink 42 and the package mounting plate 23 are grounded as illustrated in FIG. 10, a shield effect of blocking noises from the outside may be produced because the semiconductor device 10 is interposed between the conductors. Specifically, it is preferable to connect the heat sink 42 and the package mounting plate 23 to a frame ground (FG) or a signal ground (SG).

For example, the package mounting plate 23 may be electrically connected to the signal ground (SG) by providing the connection terminals 55 in the package mounting plate 23 as in FIG. 7B. In this case, the shield effect described above may be obtained by electrically connecting the heat sink 42 to the package mounting plate 23.

### Modified Example 5

In the embodiment described above, the air blowing fans 43 are turned on and the air valve 48 is opened when the temperature of the semiconductor device 10 exceeds the set temperature. However, the air blowing fans 43 and the air valve 48 may be PID (Proportional-Integral-Derivative) controlled.

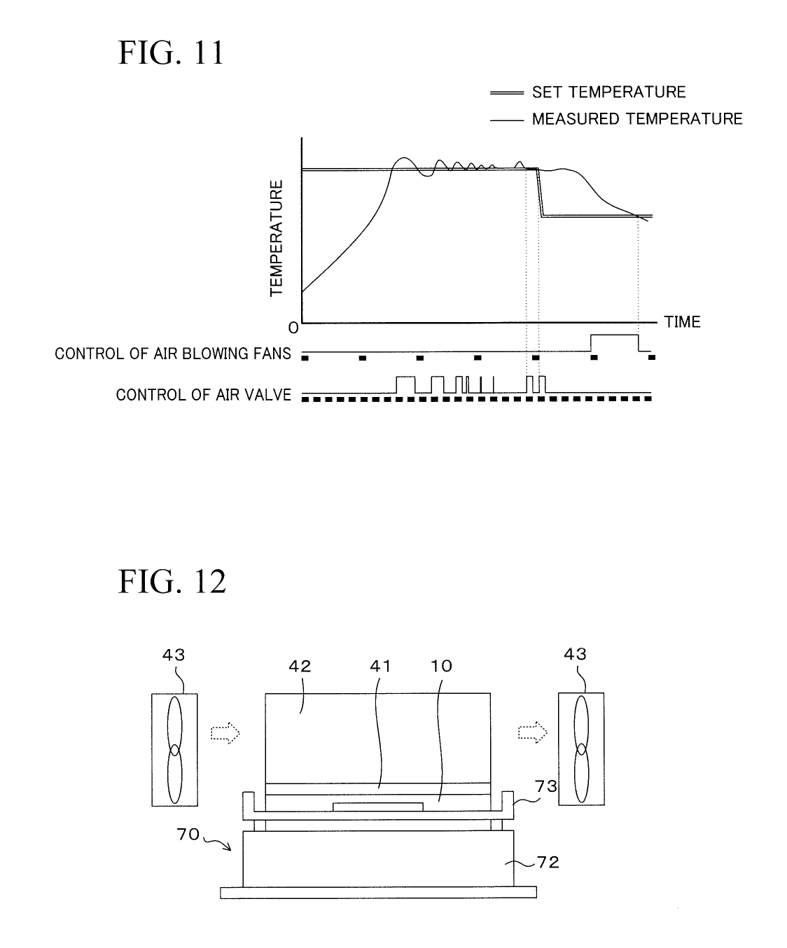

FIG. 11 is a graph explaining an example of the PID control, where the horizontal axis represents time and the vertical axis represents temperature. In FIG. 11, black squares (□) indicate timings at which the air blowing fans 43 and the air valve 48 are controlled by sampling the output of the temperature sensor included in the semiconductor device 10 (or the temperature sensor detecting the surface temperature of the semiconductor device 10).

The air blowing fans 43 are controlled based on a measured temperature obtained by sampling the output of the temperature sensor every t seconds (for example every 0.5 seconds to several seconds). Specifically, the controller 40 checks the temperature of the semiconductor device 10 every t seconds; and when the temperature of the semiconductor device 10 approaches the set temperature, the controller 40 turns the air blowing fans 43 on or off according to the difference between the set temperature and the measured temperature, the change rate of the temperature, and the like.

Meanwhile, the air valve 48 is controlled based on a measured temperature obtained by sampling the output of the temperature sensor every t/n seconds (n is a number equal to or larger than 2, preferably a number equal to or larger than 10). Specifically, the controller 40 checks the temperature of the semiconductor device 10 every t/n seconds; and when the temperature of the semiconductor device 10 approaches the set temperature, the controller 40 turns the air valve 48 on or off according to the difference between the set temperature and the measured temperature and the change rate of the temperature.

In Modified Example 5, as illustrated in FIG. 11, the test jig copes with a large change in the temperature of the semiconductor device 10 by turning the air blowing fans 43 on and off and copes with a small change in the temperature of the semiconductor device 10 by turning the air valve 48 on and off. The temperature of the semiconductor device 10 may be thereby controlled more appropriately.

Note that the numbers of revolutions of the air blowing fans 43 and the air blow amount may be controlled according to the difference between the set temperature and the measured temperature, the change rate of the measured temperature, and the like.

### Example

Effects obtained when an accelerated test is performed by using the test jig according to the embodiment are described below by comparing an example with a comparative example.

The test jig 20 having the structure illustrated in FIG. 1 is prepared as the example. The package mounting plate 23 is fabricated by using copper. The outside dimensions of the package mounting plate 23 are 66.5 mm (length)×66.5 mm (width)×5.0 mm (height) and the thickness of a package mounting portion at the center is 2.0 mm. Moreover, the outside dimensions of the socket portion 22 are 86.0 mm (length)×86.0 mm (width)×11.0 mm (height) and the socket portion 22 is fabricated by using aluminum and FR4 stacked resin material.

Moreover, a test jig 70 having a structure illustrated in FIG. 12 is prepared as a comparative example. The test jig 70 of the comparative example is different from the example in that a package mounting plate 73 is made of polyether resin (ULTEM: registered trademark).

A CPU (SPARC64 IV: SPARC64 is a registered trademark) for an UNIX (registered trademark) server is attached to each of the test jig 20 of the example and the test jig 70 of the comparative example as the semiconductor device 10. The size of the semiconductor device 10 is 42.5 mm (length)×42.5 mm (width)×4.54 mm (height). Then, an accelerated test is performed under the following conditions. The set temperature is 80° C., the consumed power is 380 W, the load fluctuation is +30 mV of a set voltage, and the room temperature is 25° C. In the accelerated test, air is made to blow on a back surface side of the package mounting plate from below the socket portion at a flow rate of 70 liters per minute.

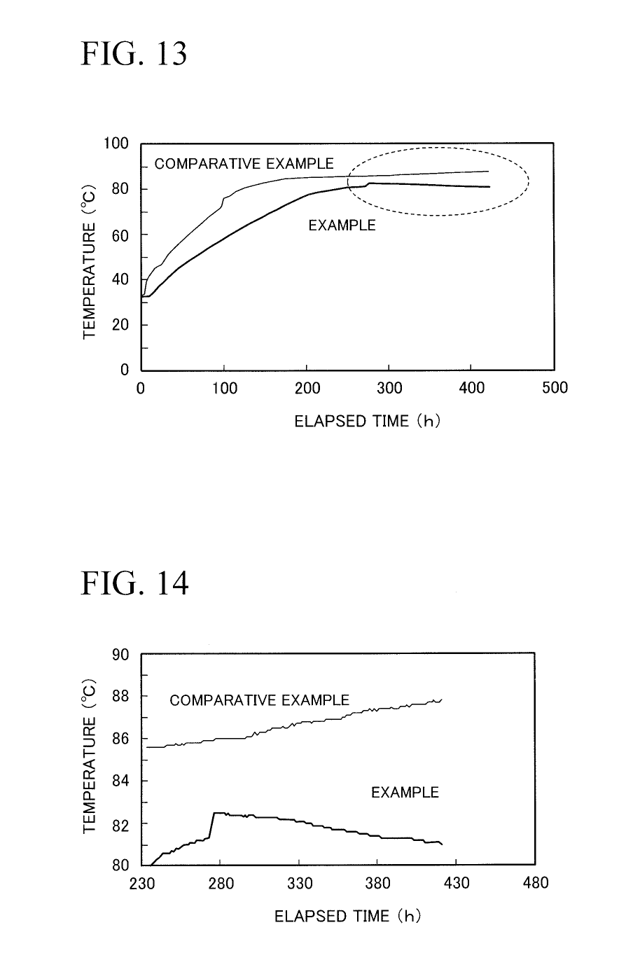

FIG. 13 is a graph illustrating the temperature change of the CPU, where the horizontal axis represents time and the vertical axis represents temperature. Moreover, FIG. 14 is a view illustrating a portion surrounded by a broken line in FIG. 13 in an enlarged manner.

As is apparent from FIGS. 13 and 14, the temperature is controlled to be +3° C. of the set temperature or lower in the test jig 20 of the example. Meanwhile it is found that the temperature becomes higher than the set temperature by about +8° C. in the test jig 70 of the comparative example and the temperature control is insufficient.

Moreover, it is apparent from FIGS. 13 and 14 that the time elapsing before the temperature reaches the set temperature is short in the test jig 70 of the comparative example while the time elapsing before the temperature reaches the set temperature is long in the test jig 20 of the example. This is due to the following reason. Since the package mounting plate 23 is made of metal in the test jig 20 of the example, the thermal resistance is small and the thermal capacity is large.

Furthermore, the following fact is apparent from FIGS. 13 and 14. Since the package mounting plate 73 is made of resin in the test jig 70 of the comparative example, the thermal resistance is large and the package mounting plate 73 does not follow the temperature change of the semiconductor device (CPU) 10.

The effectiveness of the test jig according to the embodiment may be confirmed from the experimental results described above.

All examples and conditional language recited herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A test jig comprising:
a package mounting plate on which a semiconductor device is placed;
a plurality of penetrating holes provided in the package mounting plate;
a socket portion in which a plurality of probe pins are disposed, the probe pins designed to come in contact with electrodes of the semiconductor device through the plurality of penetrating holes; and
a gas injecting unit configured to inject gas to the package mounting plate through the socket portion.

2. The test jig according to claim 1, wherein the package mounting plate is made of metal.

3. The test jig according to claim 1, wherein the socket portion is formed by combining an insulating member in contact with the probe pins and a metal member out of contact with the probe pins.

4. The test jig according to claim 1, wherein the package mounting plate is provided with a heater or a Peltier element.

5. The test jig according to claim 1, wherein the package mounting plate is provided with a heating medium flow passage through which a heating medium flows.

6. The test jig according to claim 2, wherein the package mounting plate is provided with a connection terminal designed to come in contact with a specific electrode out of the electrodes of the semiconductor device.

7. The test jig according to claim 1, wherein the package mounting plate is provided with a hole configured to guide the gas injected from the gas injecting unit to the semiconductor device.

8. The test jig according to claim 1, wherein the socket portion is provided with a damper configured to be opened and closed by wind pressure of the gas injected from the gas injecting unit.

9. A semiconductor device test method of testing a semiconductor device by: placing the semiconductor device on a test jig in which a probe pin is installed; and supplying a signal from a controller to the semiconductor device via the probe pin, wherein
the test jig comprises: a package mounting plate on which the semiconductor device is placed; a penetrating hole provided in the package mounting plate and allowing insertion of a front end portion of the probe pin; a socket portion in which the probe pin is disposed; and a gas injecting unit configured to inject gas, and
the method comprises testing the semiconductor device while injecting the gas from the gas injecting unit to the package mounting plate through the socket portion.

10. The semiconductor device test method according to claim 9, wherein a heat sink is attached to a surface of the semiconductor device on an opposite side to a package mounting plate and the heat sink is cooled by an air blowing fan.

11. The semiconductor device test method according to claim 10, wherein the controller controls the air blowing fan and injection of the gas from the gas injecting unit, according to a temperature of the semiconductor device.

12. The semiconductor device test method according to claim 11, wherein the controller controls the air blowing fan at intervals of a first time period, and controls the injection of the gas from the gas injecting unit at intervals of a second time period being shorter than the first time period.

13. The semiconductor device test method according to claim 9, wherein the package mounting plate is made of metal.

14. The semiconductor device test method according to claim 9, wherein the socket portion is formed by combining an insulating member in contact with the probe pin and a metal member out of contact with the probe pin.

15. The semiconductor device test method according to claim 9, wherein the package mounting plate is provided with a connection terminal designed to come in contact with a specific electrode out of electrodes of the semiconductor device.
